(19) United States
(12) Patent Application Publication
(10) Pub. No.: US 2012/0132282 A1
(43) Pub. Date: May 31, 2012

(54) ALKALI-FREE HIGH STRAIN POINT GLASS

(76) Inventors: Bruce Gardiner Aitken, Corning, NY (US); James Edward Dickinson, JR., Corning, NY (US)

(21) Appl. No.: 13/305,051

(22) Filed: Nov. 28, 2011

Related U.S. Application Data
(60) Provisional application No. 61/418,084, filed on Nov. 30, 2010.
(60) Provisional application No. 61/503,248, filed on Jun. 30, 2011.
(60) Provisional application No. 61/562,651, filed on Nov. 22, 2011.

(51) Int. Cl. C03C 3/093; C03C 3/14; C03C 3/145; C03C 3/078; C03C 3/089; C03C 3/091; C03C 3/085; C03C 3/087; C03C 3/062; C03C 3/064; C03C 3/066; B32B 5/00; H01L 31/02; H01L 31/0272; C03C 3/12

(52) U.S. Cl. 136/260; 501/41; 501/49; 501/52; 501/72; 501/65; 501/66; 501/67; 501/69; 501/70; 501/73; 501/77; 501/79; 428/220; 136/262; 136/252

(57) ABSTRACT

A compositional range of high strain point alkali metal free, silicate, aluminosilicate and boroaluminosilicate glasses are described herein. The glasses can be used as substrates for photovoltaic devices, for example, thin film photovoltaic devices such as CIGS photovoltaic devices. These glasses can be characterized as having strain points ≧570° C., thermal expansion coefficient of from 5 to 9 ppm/° C.

This application claims the benefit of priority under 35 U.S.C. §119 of U.S. Provisional Application Ser. No. 61/418,084 filed on Nov. 30, 2010, U.S. Provisional Application Ser. No. 61/503,248 filed on Jun. 30, 2011, and to U.S. Provisional Application Ser. No. 61/562,651 filed on Nov. 22, 2011, the contents of which are relied upon and incorporated herein by reference in its entirety.

### BACKGROUND

1. Field

Embodiments relate generally to alkali-free glasses and more particularly to alkali-free, high strain point aluminate, aluminosilicate, borosilicate and boroaluminosilicate glasses with high thermal expansion coefficient which may be useful in photovoltaic applications, for example, thin film photovoltaic devices.

2. Technical Background

Substrate glasses for copper indium gallium diselenide (CIGS) photovoltaic modules typically contain Na₂O, as diffusion of Na from the glass into the CIGS layer has been shown to result in significant improvement in module efficiency. However, due to the difficulty in controlling the amount of diffusing Na during the CIGS deposition/crystallization process, some manufacturers of these devices prefer to deposit a layer of a suitable Na compound, e.g. NaF, prior to CIGS deposition, in which case any alkali present in the substrate glass needs to be contained through the use of a barrier layer. Moreover, in the case of cadmium telluride (CdTe) photovoltaic modules, any alkali contamination of the CdTe layer is deleterious to module efficiency and, therefore, typical alkali-containing substrate glasses, e.g. soda-lime glass, require the presence of a barrier layer. Consequently, use of an alkali-free substrate glass for either CIGS or CdTe modules can obviate the need for a barrier layer.

### SUMMARY

The high thermal expansion coefficient of the disclosed glasses makes them especially compatible with CIGS, as previous work has typically shown poor CIGS adhesion to substrates having a thermal expansion coefficient <5 ppm/° C. Substrates having a thermal expansion coefficient >5 ppm/° C., for example, >7 ppm/° C. may be advantageous.

One embodiment is a glass comprising, in mole percent:
0 to 70 percent SiO₂;
0 to 35 percent Al₂O₃;
0 to 30 percent B₂O₃;
0 to 12 percent MgO;
0 to 20 percent SrO;
0 to 67 percent CaO; and
0 to 33 percent BaO,
wherein MgO+CaO+BaO+SrO is 15 to 68 percent and wherein the glass is substantially free of alkali metal.

Another embodiment is a glass comprising, in mole percent:
0 to 43 percent SiO₂;
0 to 35 percent Al₂O₃;
0 to 30 percent B₂O₃;
0 to 12 percent MgO;
0 to 67 percent CaO; and
0 to 33 percent BaO,
wherein MgO+CaO+BaO is 30 to 68 percent and wherein the glass is substantially free of alkali metal.

Another embodiment is a glass comprising, in mole percent:
0 to 43 percent SiO₂;
0 to 35 percent Al₂O₃;
0 to 30 percent B₂O₃;
0 to 12 percent MgO;
0 to 67 percent CaO;
0 to 19 percent SrO;
0 to 5 percent ZnO; and
0 to 33 percent BaO,
wherein MgO+CaO+BaO is 30 to 68 percent and wherein the glass is substantially free of alkali metal.

These glasses are advantageous materials to be used in copper indium gallium diselenide (CIGS) photovoltaic modules where the sodium required to optimize cell efficiency is not to be derived from the substrate glass but instead from a separate deposited layer consisting of a sodium containing material such as NaF. Current CIGS module substrates are typically made from soda-lime glass sheet that has been manufactured by the float process. However, use of higher strain point glass substrates can enable higher temperature CIGS processing, which is expected to translate into desirable improvements in cell efficiency.

Accordingly, the alkali-free glasses described herein can be characterized by strain points ≧570° C. and thermal expansion coefficients in the range of from 50 to 90×10⁻⁷/° C. (5 to 9 ppm/° C.), in order to avoid thermal expansion mismatch between the substrate and CIGS layer or to better match the thermal expansion of CdTe.

Embodiments of the alkali-free glasses described herein can be characterized by strain points ≧570° C. and thermal expansion coefficients in the range of from 7 to 9 ppm/° C., in order to avoid thermal expansion mismatch between the substrate and CIGS layer.

Finally, the preferred compositions of this disclosure have strain point well in excess of 650° C., thereby enabling CIGS or CdTe deposition/crystallization to be carried out at the highest possible processing temperature, resulting in additional efficiency gain.

Additional features and advantages will be set forth in the detailed description which follows, and in part will be readily apparent to those skilled in the art from the description or recognized by practicing the invention as described in the written description and claims hereof.

It is to be understood that both the foregoing general description and the following detailed description are merely exemplary of the invention, and are intended to provide an overview or framework for understanding the nature and character of the invention as it is claimed.

The accompanying drawing is included to provide a further understanding of the invention, and is incorporated in and constitutes a part of this specification. The drawing illustrates one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing FIGURE.

FIG. 1 is a schematic of features of a photovoltaic device according to some embodiments.

### DETAILED DESCRIPTION

Reference will now be made in detail to various embodiments of the invention.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

As used herein, the term “adjacent” can be defined as being in close proximity. Adjacent structures may or may not be in physical contact with each other. Adjacent structures can have other layers and/or structures disposed between them.

One embodiment is a glass comprising, in mole percent:
0 to 70 percent SiO₂;
0 to 35 percent Al₂O₃;
0 to 30 percent B₂O₃;
0 to 12 percent MgO;
0 to 20 percent SrO;
0 to 67 percent CaO; and
0 to 33 percent BaO,
wherein MgO+CaO+BaO+SrO is 15 to 68 percent and wherein the glass is substantially free of alkali metal.

Another embodiment is a glass comprising, in mole percent:
0 to 43 percent SiO₂;
0 to 35 percent Al₂O₃;
0 to 30 percent B₂O₃;
0 to 12 percent MgO;
0 to 67 percent CaO; and
0 to 33 percent BaO,
wherein MgO+CaO+BaO is 30 to 68 percent and wherein the glass is substantially free of alkali metal.

Another embodiment is a glass comprising, in mole percent:
0 to 43 percent SiO₂;
0 to 35 percent Al₂O₃;
0 to 30 percent B₂O₃;
0 to 12 percent MgO;
0 to 67 percent CaO;
0 to 19 percent SrO;
0 to 5 percent ZnO; and
0 to 33 percent BaO,
wherein MgO+CaO+BaO is 30 to 68 percent and wherein the glass is substantially free of alkali metal.

In one embodiment, the glass, comprises, in mole percent:
45 to 70 percent SiO₂;
5 to 16 percent Al₂O₃;
0 to 10 percent B₂O₃;
0 to 10 percent MgO;
0 to 15 percent SrO;
7 to 35 percent CaO; and
0 to 10 percent BaO,
wherein MgO+CaO+BaO+SrO is 18 to 40 percent and wherein the glass is substantially free of alkali metal.

The glass is substantially free of alkali metal, for example, the content of alkali can be 0.05 mole percent or less, for example, zero mole percent. The glass, according to some embodiments, is free of intentionally added alkali metal.

In some embodiments, the glass comprises greater than zero mole percent of at least one of the following: MgO, BaO, or B₂O₃, for example, at least 1 mole percent of at least one of the following: MgO, BaO, or B₂O₃.

In some embodiments, the glass comprises 0 to 43 percent SiO₂, for example, 5 to 43 percent SiO₂.

The glass, in one embodiment, is rollable. According to another embodiment, the glass can be float formed.

As mentioned above, the glasses, according some embodiments, comprise 0 to 30 percent B₂O₃, for example, 1 to 30 percent. B₂O₃ is added to the glass to reduce melting temperature, to decrease liquidus temperature, to increase liquidus viscosity, and to improve mechanical durability relative to a glass containing no B₂O₃.

The glass, according to some embodiments, comprises MgO+CaO+BaO in an amount from 30 to 68 percent. MgO can be added to the glass to reduce melting temperature and to increase strain point. It can disadvantageously lower CTE relative to other alkaline earths (e.g., CaO, SrO, BaO), and so other adjustments may be made to keep the CTE within the desired range. Examples of suitable adjustments include increase SrO at the expense of CaO, increasing alkaline earth oxide concentration, and replacing a smaller alkaline earth oxide in part with a larger alkaline earth oxide.

In some embodiments, the glass is substantially free of Sb₂O₃, As₂O₃, or combinations thereof, for example, the glass comprises 0.05 mole percent or less of Sb₂O₃ or As₂O₃ or a combination thereof. For example, the glass can comprise zero mole percent of Sb₂O₃ or As₂O₃ or a combination thereof.

The glasses, in some embodiments, comprise 0 to 67 mole percent CaO, for example, 10 to 67 mole percent CaO. CaO contributes to higher strain point, lower density, and lower melting temperature.

The glass according to one embodiment, further comprises 0 to 20 percent of one or more of SrO, ZnO, SnO₂, ZrO₂. The glasses can comprise, in some embodiments, 0 to 12 mole percent SrO, for example, greater than zero to 12 mole percent, for example, 1 to 12 mole percent SrO, or for example, 0 to 5 mole percent SrO, for example, greater than zero to 5 mole percent, for example, 1 to 5 mole percent SrO. In certain embodiments, the glass contains no deliberately batched SrO, though it may of course be present as a contaminant in other batch materials. SrO contributes to higher coefficient of thermal expansion, and the relative proportion of SrO and CaO can be manipulated to improve liquidus temperature, and thus liquidus viscosity. SrO is not as effective as CaO or MgO for improving strain point, and replacing either of these with SrO tends to cause the melting temperature to increase.

Accordingly, in one embodiment, the glass has a strain point of 570° C. or greater, for example, 580° C. or greater, for example, 590° C. or greater, for example, 650° C. or greater. In some embodiments, the glass has a coefficient of thermal expansion of 50×10⁻⁷ or greater, for example, 60×10⁻⁷ or greater, for example, 70×10⁻⁷ or greater, for example, 80×10⁻⁷ or greater. In one embodiment, the glass has a strain point of from 50×10⁻⁷ to 90×10⁻⁷.

In one embodiment, the glass has a coefficient of thermal expansion of 50×10⁻⁷ or greater and a strain point of 570° C. or greater. In one embodiment, the glass has a coefficient of thermal expansion of 50×10⁻⁷ or greater and a strain point of 650° C. or greater.

According to one embodiment, the glass can be float formed as known in the art of float forming glass. Embodiments having a liquidus viscosity of greater than or equal to 10 kP are usually float formable.

In one embodiment, the glass is in the form of a sheet. The glass in the form of a sheet can be thermally tempered.

The glass, according to one embodiment, is transparent.

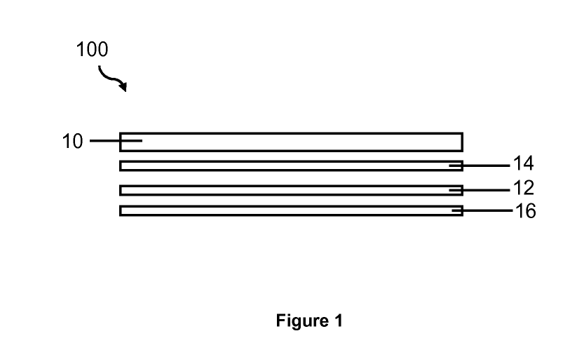

In one embodiment, as shown in FIG. 1, a photovoltaic device 100 comprises the glass in the form of a sheet 10. The photovoltaic device can comprise more than one of the glass sheets, for example, as a substrate and/or as a superstrate. In one embodiment, the photovoltaic device 100 comprises the glass sheet as a substrate and/or superstrate 10, a conductive material 12 adjacent to the substrate, and an active photovoltaic medium 16 adjacent to the conductive material. In one embodiment, the active photovoltaic medium comprises a CIGS layer. In one embodiment, the active photovoltaic medium comprises a cadmium telluride (CdTe) layer. In one embodiment, the photovoltaic device comprises a functional layer comprising copper indium gallium diselenide or cadmium telluride. In one embodiment, the photovoltaic device the functional layer is copper indium gallium diselenide. In one embodiment, the functional layer is cadmium telluride.

In one embodiment, the photovoltaic device comprises more than one sheet of an embodiment of the described glasses. One can be on the side of the device incident to sunlight and another glass sheet on the non-incident side. Another sheet can be disposed at any location in the module, for example.

The photovoltaic device 100, according to one embodiment, further comprises a barrier layer and/or an alkali containing layer 14 disposed between or adjacent to the superstrate or substrate and the functional layer. In one embodiment, the photovoltaic device further comprises a barrier layer disposed between or adjacent to the superstrate or substrate and a transparent conductive oxide (TCO) layer, wherein the TCO layer is disposed between or adjacent to the functional layer and the barrier layer. A TCO may be present in a photovoltaic device comprising a CdTe functional layer. In one embodiment, the barrier layer is disposed directly on the glass.

The photovoltaic device, according to one embodiment, further comprises an alkali containing layer disposed between or adjacent to the superstrate or substrate and the functional layer. In one embodiment, the photovoltaic device further comprises an alkali containing layer disposed between or adjacent to the superstrate or substrate and a transparent conductive oxide (TCO) layer, wherein the TCO layer is disposed between or adjacent to the functional layer and the alkali containing layer. A TCO may be present in a photovoltaic device comprising a CdTe functional layer. In one embodiment, the alkali containing layer is disposed directly on the glass.

In one embodiment, the glass sheet is optically transparent. In one embodiment, the glass sheet as the substrate and/or superstrate is optically transparent.

According to some embodiments, the glass sheet has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass sheet can have a thickness of any numerical value including decimal places in the range of from 0.1 mm up to and including 4.0 mm.

Embodiments of glasses, by virtue of their relatively high strain point, represent advantaged substrate materials for CIGS photovoltaic modules as they can enable higher temperature processing of the critical semiconductor layers.

Examples of glasses of this disclosure are given in the following table in terms of mol %. Relevant physical properties are reported for most examples, where Tₛₜᵣ, Tₐₙₙ, α, ρ refer to strain point, anneal point, thermal expansion coefficient and density, respectively. Glasses that have a difference between Tₐₙₙ and Tₛₜᵣ is ≦30° C. are expected to have Tₛₜᵣ in excess of 650° C. Glasses which have T_{ann ≧}700° C. and, therefore, have Tₛₜᵣ ≧650° C. may be preferred compositions.

Embodiments of the disclosed glasses have Tstr >640° C., α of 50-70×10⁻⁷/° C. and comprise, in mol %, 0-10 MgO, 7-35 CaO, 0-15 SrO, 0-10 BaO, such that MgO+CaO+SrO+BaO ranges 18-40, 0-10 B₂O₃, 5-16 Al₂O₃ and 45-70 SiO₂. These glasses are typically fined with about 0.05-0.2% SnO₂. Optional components that can be used to further tailor glass properties include 0-2% TiO₂, MnO, ZnO, Nb₂O₅, Ta₂O₅, ZrO₂, La₂O₃, Y₂O₃ and/or P₂O₅.

Alkali-free glasses are becoming increasingly attractive candidates for the superstrate, substrate of CdTe, CIGS modules, respectively. In the former case, alkali contamination of the CdTe and conductive oxide layers of the film stack is avoided. Moreover, process simplification arises from the elimination of the barrier layer (needed, e.g., in the case of conventional soda-lime glass). In the latter case, CIGS module manufacturers are better able to control the amount of Na needed to optimize absorber performance by depositing a separate Na-containing layer that, by virtue of its specified composition and thickness, results in more reproducible Na delivery to the CIGS layer. Glasses that have been disclosed to date have been characterized by a thermal expansion coefficient (α) that is either in the 70-90×10⁻⁷/° C. range so as to match that of soda-lime glass, or (b) in the 40-50×10⁻⁷/° C. range so as to enable manufacturing via the fusion process. However, a of CdTe is on the order of 55×10⁻⁷/° C. and it is possible that CdTe cell performance may be optimized if the glass superstrate and CdTe film are α-matched. Thus, there may be a need for alkali-free glasses with a in the range of 50-70×10⁻⁷/° C.

### EXAMPLES

Table 1, Table 2, Table 3, Table 4, Table 5, Table 6, Table 7, Table 8, Table 9, Table 10, Table 11, and Table 12 show exemplary glasses, according to embodiments of the invention. Property data for some exemplary glasses are also shown in Table 1, Table 2, Table 3, Table 4, Table 5, Table 6, Table 7, Table 8, Table 9, Table 10, Table 11, and Table 12.

In the Tables Tₛₜᵣ(° C.) is the strain point which is the temperature when the viscosity is equal to 10^{14.7} P as measured by beam bending or fiber elongation. Tₐₙₙ(° C.) is the annealing point which is the temperature when the viscosity is equal to 10^{13.18} P as measured by beam bending or fiber elongation. Tₛ(° C.) is the softening point which is the temperature when the viscosity is equal to 10^{7.6} P as measured by beam bending or fiber elongation. α(10⁻⁷/° C.) or a(10⁻⁷/° C.) or CTE in the Tables is the coefficient of thermal expansion (CTE) which is the amount of dimensional change from either 0 to 300° C. or 25 to 300° C. depending on the measurement. CTE is typically measured by dilatometry. r(g/cc) or ρ is the density which is measured with the Archimedes method (ASTM C693). T₂₀₀(° C.) is the two-hundred Poise (P) temperature. This is the temperature when the viscosity of the melt is 200 P as measured by HTV (high temperature viscosity) measurement which uses concentric cylinder viscometry. T_{liq}(° C.) is the liquidus temperature. This is the temperature where the first crystal is observed in a standard gradient boat liquidus measurement (ASTM C829-81). Generally this test is 72 hours but can be as short as 24 hours to increase throughput at the expense of accuracy (shorter tests could underestimate the liquidus temperature). η_{liq}(° C.) is the liquidus viscosity. This is the viscosity of the melt corresponding to the liquidus temperature.

TABLE 1

| | Example | | | | | | |
|---|---|---|---|---|---|---|---|
| Mole % | 1 | 2 | 3 | 4 | 5 | 6 | 7 |
| MgO | 10.7 | 9.3 | | | | | 5.3 |
| CaO | 49.3 | 50.7 | 60 | 65 | 65 | 60 | 24.7 |
| BaO | 6.7 | 6.7 | | | | | 18.8 |
| RO | 66.7 | 66.7 | 60 | 65 | 65 | 60 | 48.8 |
| B₂O₃ | | | | | | | 14 |
| Al₂O₃ | 33.3 | 33.3 | 35 | 30 | 25 | 25 | 16.7 |
| SiO₂ | | | 5 | 5 | 10 | 15 | 20.5 |
| Tₛₜᵣ | | | | | | | 597 |
| Tₐₙₙ | 767 | 747 | | | | | 636 |
| α | ~80 | 79.5 | 79.2 | 85.3 | 86.7 | 84 | 86 |
| ρ | 3.131 | 3.132 | | | | | |

TABLE 2

| | Example | | | | | | |
|---|---|---|---|---|---|---|---|
| Mole % | 8 | 9 | 10 | 11 | 12 | 13 | 14 |
| MgO | 8 | 5.3 | 2.7 | | | | |
| CaO | 44.9 | 40.4 | 36 | | 31.5 | | 10.5 |
| BaO | 6.9 | 7.2 | 7.5 | 31 | 7.8 | 31 | 23.3 |
| RO | 59.8 | 52.9 | 46.2 | 31 | 39.3 | 31 | 33.8 |
| B₂O₃ | 7 | 14 | 21 | 28 | 28 | 23 | 23 |
| Al₂O₃ | 25 | 20.5 | 30.8 | | | 5 | 5 |
| SiO₂ | 8.2 | 16.4 | 24.6 | 41 | 32.8 | 41 | 38.2 |
| Tₛₜᵣ | 691 | 615 | 577 | 597 | 599 | 580 | 586 |
| Tₐₙₙ | 728 | 651 | 610 | 631 | 633 | 617 | 622 |
| α | 83.9 | 86.3 | 86 | 82.8 | 81.2 | 81.1 | 79.6 |
| ρ | | | | | | | |

TABLE 3

| | Example | | |
|---|---|---|---|
| Mole % | 15 | 16 | 17 |
| MgO | | | |
| CaO | 49 | 42 | 50 |
| BaO | | | |
| RO | 49 | 42 | 50 |
| B₂O₃ | 28 | 28 | 20 |
| Al₂O₃ | | | |
| SiO₂ | 23 | 30 | 30 |
| Tₛₜᵣ | 598 | 607 | 580 |
| Tₐₙₙ | 630 | 639 | 612 |
| α | 89.3 | 80.1 | 94.6 |
| ρ | | | |

TABLE 4

| | Example | | | | | | |
|---|---|---|---|---|---|---|---|
| Mole % | 18 | 19 | 20 | 21 | 22 | 23 | 24 |
| MgO | 2.5 | 5 | 7.5 | 7 | 3 | 5 | 5 |
| CaO | 60 | 55 | 50 | 55 | 55 | 55 | 55 |
| BaO | 2.5 | 5 | 7.5 | 3 | 7 | 5 | 5 |
| RO | 65 | 65 | 65 | 65 | 65 | 65 | 65 |
| B₂O₃ | | | | | | 2.5 | 5 |
| Al₂O₃ | 25 | 25 | 25 | 25 | 25 | 22.5 | 20 |
| SiO₂ | 10 | 10 | 10 | 10 | 10 | 10 | 10 |
| Tₛₜᵣ | 745 | 731 | 724 | 730 | 733 | 708 | 696 |
| Tₐₙₙ | 780 | 768 | 763 | 767 | 770 | 746 | 733 |
| α | 84.5 | 84.8 | 84.2 | 84 | 86.4 | 86.8 | 91.6 |
| ρ | | | | | | | |

TABLE 5

| | Example | |
|---|---|---|
| Mole % | 25 | 26 |
| MgO | 5 | 9.4 |
| CaO | 55 | 50.4 |
| BaO | 5 | 6.7 |
| RO | 65 | 66.4 |
| B₂O₃ | 5 | |
| Al₂O₃ | 21.4 | 33.4 |
| Sb₂O₃ | | 0.2 |
| SiO₂ | 8.6 | |
| Tₛₜᵣ | 714 | |
| Tₐₙₙ | 751 | ~750 |
| α | 84.7 | 79.7 |
| ρ | 3.131 | |

TABLE 6

| | Example | | | | | | | | | |
|---|---|---|---|---|---|---|---|---|---|---|
| Mole % | 27 | 28 | 29 | 30 | 31 | 32 | 33 | 34 | 35 | 36 |
| MgO | | | | | | | | | | |
| CaO | 28.5 | 28.5 | 28.5 | 28.5 | 28.5 | 28.5 | 30 | 30 | 30 | 27 |
| SrO | 19 | 19 | 19 | 19 | 19 | 19 | 17.5 | 17.5 | 17.5 | 18 |
| ZnO | | | | | | | | | | |
| B2O3 | 25 | 20 | 20 | 15 | 15 | 10 | 22.5 | 20 | 17.5 | 15 |
| Al2O3 | 15 | 20 | 15 | 20 | 15 | 20 | 15 | 17.5 | 20 | 20 |
| SiO2 | 12.5 | 12.5 | 17.5 | 17.5 | 22.5 | 22.5 | 15 | 15 | 15 | 20 |
| SnO2 | | | | | | | | | | |
| Tstr | 564 | 590 | 581 | 618 | 605 | 651 | 570 | 585 | 603 | 617 |
| Tann | 597 | 626 | 615 | 656 | 641 | 690 | 604 | 621 | 640 | 655 |
| CTE | 88 | 86.8 | 89.4 | 82.8 | 86.7 | 82.6 | 84.4 | 85.4 | 82.2 | 80.6 |
| R | 3.069 | 3.063 | 3.09 | 3.085 | 3.108 | 3.122 | 3.057 | 3.06 | 3.054 | 3.054 |
| Tliq | no devit | 1020 | 1330 | 1240 | 1120 | 1340 | no devit | 1080 | 1190 | <1200 |
| RO | 47.5 | 47.5 | 47.5 | 47.5 | 47.5 | 47.5 | 47.5 | 47.5 | 47.5 | 45 |

TABLE 7

| | Example | | | | | | | |
|---|---|---|---|---|---|---|---|---|
| Mole % | 37 | 38 | 39 | 40 | 41 | 42 | 43 | 44 |
| MgO | | | 5 | 10 | | 5 | 10 | |
| CaO | 25.5 | 24 | 24 | 21 | 24 | 21 | 18 | 21 |
| SrO | 17 | 16 | 16 | 14 | 16 | 14 | 12 | 14 |
| ZnO | | | | | 5 | | | 5 |
| B2O3 | 15 | 15 | 15 | 15 | 15 | 15 | 15 | 15 |
| Al203 | 20 | 20 | 20 | 20 | 20 | 20 | 20 | 20 |
| SiO2 | 22.5 | 25 | 20 | 20 | 20 | 25 | 25 | 25 |
| SnO2 | | | | | | | | |
| Tstr | ~615 | ~615 | 619 | 618 | 602 | 620 | 621 | 606 |
| Tann | ~650 | ~650 | 657 | 655 | 639 | 657 | 659 | 644 |
| CTE | ~80 | ~80 | 73.7 | 77.6 | 76.3 | 70 | 67.3 | 69.9 |
| r | 3.021 | 2.986 | | | | | | |
| Tliq | <1200 | | | | | | | |
| RO | 42.5 | 40 | 45 | 45 | 45 | 40 | 40 | 40 |

TABLE 8

| | Example | | | | |
|---|---|---|---|---|---|
| Mole % | 45 | 46 | 47 | 48 | 49 |
| MgO | | 2.9 | | 2.35 | 1.9 |
| CaO | 17.2 | 32.1 | 13.2 | 25.6 | 20.8 |
| SrO | 11.5 | | 8.7 | | |
| BaO | | 2.9 | | 2.35 | 1.9 |
| RO | 28.7 | 37.9 | 21.9 | 30.3 | 24.6 |
| B2O3 | 8 | | 8 | | |
| Al2O3 | 13.3 | 14.6 | 10.1 | 11.7 | 9.4 |
| SiO2 | 49.9 | 47.4 | 59.9 | 57.9 | 65.9 |
| SnO2 | 0.1 | 0.1 | 0.1 | 0.1 | 0.1 |
| Tₛₜᵣ | 657 | ~700 | 648 | 710 | 715 |
| α | 60 | ~66 | 50.4 | 57.5 | 50.3 |
| ρ | 2.848 | 2.885 | 2.696 | 2.771 | 2.664 |

TABLE 9

| | Example | | | | |
|---|---|---|---|---|---|
| Mole % | 50 | 51 | 52 | 53 | 54 |
| MgO | 2.1 | 2.1 | 2 | 2 | 2.2 |
| CaO | 21.2 | 20.6 | 20.1 | 19.85 | 21.65 |
| SrO | | | | | |
| BaO | 2.1 | 2.1 | 2 | 2 | 2.2 |
| RO | 25.4 | 24.8 | 24.1 | 23.85 | 26.05 |
| B2O3 | 2.5 | 5 | 7.5 | | |
| Al2O3 | 8.8 | 8.6 | 8.4 | 8.25 | 6.05 |
| SiO2 | 63.2 | 61.5 | 59.9 | 67.8 | 67.8 |
| SnO2 | 0.1 | 0.1 | 0.1 | 0.1 | 0.1 |
| Tₛₜᵣ | 676 | ~660 | 643 | 711 | 699 |
| α | 52.8 | ~52.5 | 52.2 | 50.4 | 54.6 |
| ρ | 2.674 | ~2.66 | 2.64 | 2.652 | 2.675 |
| T_{liq} | 1120 | 1150 | 1135 | 1190 | |
| η_{liq} (kP) | | | 5.4 | | |
| T₂₀₀ | | | 1360 | | |

TABLE 10

| | Example | | | | |
|---|---|---|---|---|---|
| Mole % | 55 | 56 | 57 | 58 | 59 |
| MgO | 8.7 | 5.2 | 8.5 | 8.3 | 8.05 |
| CaO | 8.7 | 10.45 | 8.5 | 8.3 | 8.05 |
| SrO | | 5.2 | | | |
| BaO | 8.65 | 5.2 | 8.4 | 8.2 | 8 |
| RO | 26.05 | 26.05 | 25.4 | 24.7 | 24.1 |
| B2O3 | | | 2.5 | 5 | 7.5 |
| Al2O3 | 9.05 | 9.05 | 8.8 | 8.6 | 8.4 |
| SiO2 | 64.8 | 64.8 | 63.2 | 61.6 | 59.9 |
| SnO2 | 0.1 | 0.1 | 0.1 | 0.1 | 0.1 |
| Tₛₜᵣ | 704 | 703 | ~680 | ~655 | 633 |
| α | 52.4 | 53.5 | ~52 | ~51.5 | 51 |
| ρ | 2.865 | 2.853 | ~2.84 | ~2.82 | 2.803 |
| T_{liq} | | | 1130 | 1125 | 1080 |
| η_{liq} (kP) | | | | | 25.1 |
| T₂₀₀ | | | | | 1383 |

TABLE 11

| | Example | | |
|---|---|---|---|
| Mole % | 60 | 61 | 62 |
| MgO | 5.1 | 4.95 | 4.8 |
| CaO | 10.15 | 9.9 | 9.6 |
| SrO | 5.1 | 4.95 | 4.8 |
| BaO | 5.1 | 4.95 | 4.8 |
| RO | 25.4 | 24.7 | 24.1 |
| B2O3 | 2.5 | 5 | 7.5 |
| Al2O3 | 8.8 | 8.6 | 8.4 |
| SiO2 | 63.2 | 61.6 | 59.9 |
| SnO2 | 0.1 | 0.1 | 0.1 |
| Tₛₜᵣ | ~680 | -660 | 639 |
| α | ~53 | ~53 | 53.1 |
| ρ | ~2.82 | ~2.80 | 2.766 |
| T_{liq} | 1135 | 1080 | 1140 |
| η_{liq} (kP) | | 40.2 | |
| T₂₀₀ | | 1420 | |

TABLE 12

| | Example | | | | | | | |
|---|---|---|---|---|---|---|---|---|
| Mole % | 63 | 64 | 65 | 66 | 67 | 68 | 69 | 70 |
| MgO | | | 4.8 | 4.8 | 4.8 | 9.5 | 9.5 | 9.5 |
| CaO | 28.5 | 38 | 26.1 | 30.9 | 35.6 | 23.8 | 28.5 | 33.3 |
| SrO | 19 | 9.5 | 16.6 | 11.8 | 7.1 | 14.2 | 9.5 | 4.7 |
| B₂O₃ | 10.5 | 10.5 | 10.5 | 10.5 | 10.5 | 10.5 | 10.5 | 10.5 |
| Al₂O₃ | 15.7 | 15.7 | 15.7 | 15.7 | 15.7 | 15.7 | 15.7 | 15.7 |
| SiO₂ | 26.3 | 26.3 | 26.3 | 26.3 | 26.3 | 26.3 | 26.3 | 26.3 |
| Tₛₜᵣ | 632 | 633 | ~630 | ~630 | ~630 | 626 | ~625 | 629 |
| Tₐₙₙ | 669 | 671 | ~665 | ~665 | ~665 | 664 | ~665 | 666 |
| α | ~85 | ~85 | ~80 | ~80 | ~80 | ~80 | ~80 | ~80 |
| ρ | | 2.986 | | | | | | |
| T_{liq} | 1210 | 1240 | 1125 | 1180 | 1200 | 1100 | 1170 | 1140 |
| RO | 47.5 | 47.5 | 47.5 | 47.5 | 47.5 | 47.5 | 47.5 | 47.5 |

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A glass comprising, in mole percent:
0 to 70 percent SiO₂;
0 to 35 percent Al₂O₃;
0 to 30 percent B₂O₃;
0 to 12 percent MgO;
0 to 67 percent CaO; and
0 to 33 percent BaO,
wherein MgO+CaO+BaO is 15 to 68 percent and wherein the glass is substantially free of alkali metal.

2. The glass according to claim 1, in mole percent:
0 to 43 percent SiO₂;
0 to 35 percent Al₂O₃;
0 to 30 percent B₂O₃;
0 to 12 percent MgO;
0 to 67 percent CaO; and
0 to 33 percent BaO,
wherein MgO+CaO+BaO is 30 to 68 percent and wherein the glass is substantially free of alkali metal.

3. The glass, according to claim 2 comprising:
45 to 70 percent SiO₂;
5 to 16 percent Al₂O₃;
0 to 10 percent B₂O₃;
0 to 10 percent MgO;
7 to 35 percent CaO; and
0 to 10 percent BaO,
wherein MgO+CaO+BaO+SrO is 18 to 40 percent and wherein the glass is substantially free of alkali metal.

4. The glass according to claim 3, having a coefficient of thermal expansion in the range of from 50×10⁻⁷/° C. to 70×10⁻⁷/° C.

5. The glass according to claim 1, further comprising 0 to 20 percent of one or more of SrO, ZnO, SnO₂, ZrO₂.

6. The glass according to claim 1, comprising:
0 to 43 percent SiO₂;
0 to 35 percent Al₂O₃;
0 to 30 percent B₂O₃;
0 to 12 percent MgO;
0 to 67 percent CaO
0 to 20 percent SrO
0 to 20 percent ZnO; and
0 to 33 percent BaO,
wherein MgO+CaO+BaO+SrO+ZnO is 30 to 68 percent and wherein the glass is substantially free of alkali metal.

7. The glass according to claim 1, having a strain point of 570° C. or greater.

8. The glass according to claim 1, wherein the glass is in the form of a sheet.

9. The glass according to claim 8, wherein the sheet has a thickness in the range of from 0.5 mm to 4.0 mm.

10. A photovoltaic device comprising the glass according to claim 1.

11. The photovoltaic device according to claim 10, comprising a functional layer comprising copper indium gallium diselenide or cadmium telluride adjacent to the substrate or superstrate.

12. The photovoltaic device according to claim 11, further comprising an alkali containing layer disposed between the superstrate or substrate and the functional layer.

13. The glass according to claim 1, having a strain point of 570° C. or greater and a coefficient of thermal expansion of 50×10⁻⁷ or greater.

14. A glass comprising, in mole percent:
0 to 43 percent SiO₂;
0 to 35 percent Al₂O₃;
0 to 30 percent B₂O₃;
0 to 12 percent MgO;
0 to 67 percent CaO;
0 to 19 percent SrO;
0 to 5 percent ZnO; and
0 to 33 percent BaO,
wherein MgO+CaO+BaO is 30 to 68 percent and wherein the glass is substantially free of alkali metal.

15. The glass according to claim 14, further comprising 0 to 5 percent of one or more of TiO₂, ZrO₂.

16. The glass according to claim 14, further comprising 0 to 1 percent of one or more of SnO₂.

17. The glass according to claim 14, comprising 0-10 MgO, 18-30 CaO, 12-19 SrO, 0-5 ZnO, wherein MgO+CaO+SrO+ZnO is in the range of from 40-47.5, 10-25 B₂O₃, 15-20 Al₂O₃ and 12.5-25% SiO₂.

18. The glass according to claim 14, having a strain point of 570° C. or greater.

19. The glass according to claim 14, wherein the glass is in the form of a sheet.

20. The glass according to claim 19, wherein the sheet has a thickness in the range of from 0.5 mm to 4.0 mm.

21. A photovoltaic device comprising the glass according to claim 20.

22. The photovoltaic device according to claim 21, comprising a functional layer comprising copper indium gallium diselenide or cadmium telluride adjacent to the substrate or superstrate.

23. The photovoltaic device according to claim 22, further comprising an alkali containing layer disposed between the superstrate or substrate and the functional layer.

24. The glass according to claim 14, having a strain point of 570° C. or greater and a coefficient of thermal expansion of 50×10⁻⁷ or greater.
